(19) United States
(12) Patent Application Publication
(10) Pub. No.: US 2025/0361439 A1
(43) Pub. Date: Nov. 27, 2025

(54) QUANTUM DOT AND PREPARATION METHOD THEREOF, AND PHOTOELECTRIC DEVICE

(71) Applicants: Guangdong Juhua Research Institute of Advanced Display, Guangzhou (CN); TCL Technology Group Corporation, Huizhou (CN)

(72) Inventors: Likuan ZHOU, Guangzhou (CN); Wenjun HOU, Guangzhou (CN); Xiaolin YAN, Guangzhou (CN)

(73) Assignees: Guangdong Juhua Research Institute of Advanced Display, Guangzhou (CN); TCL Technology Group Corporation, Huizhou (CN)

(21) Appl. No.: 19/215,139

(22) Filed: May 21, 2025

(30) Foreign Application Priority Data
May 24, 2024 (CN) 202410659486.3

(51) Int. Cl. C09K 11/88; B82Y 20/00; B82Y 40/00; H10K 50/115

(52) U.S. Cl. CPC C09K 11/883; H10K 50/115; B82Y 20/00; B82Y 40/00

(57) ABSTRACT

Disclosed are a quantum dot, a photoelectric device, and an electronic apparatus. In a radial direction, the quantum dot includes a core, a first layer wrapping the core, and a second layer wrapping the first layer disposed sequentially. A band gap of the first layer is less than a band gap of the core, and the band gap of the first layer is less than a band gap of the second layer. The quantum dot has a well structure, thereby being beneficial to improve a fluorescence quantum efficiency of the quantum dot.

This application claims priority to Chinese Application No. 202410659486.3, entitled “QUANTUM DOT AND PHOTOELECTRIC DEVICE COMPRISING QUANTUM DOT”, filed on May 24, 2024. The entire disclosures of the above application are incorporated herein by reference.

### TECHNICAL FIELD

The present disclosure relates to a field of photoelectric materials, and in particular to a quantum dot and a preparation method thereof, and a photoelectric device.

### BACKGROUND

A quantum dot also known as a semiconductor nanocrystal. The quantum dot is nanocrystal with radius less than or close to an excitonic Bohr radius, and an average particle size of the quantum dot is usually between 1 nm and 30 nm. The quantum dot has a unique fluorescence nanoscale effect, and a luminous wavelength of the quantum dot might be regulated by changing size and composition. The quantum dot has advantages of narrow half-peak width of luminous spectrum, high colour purity, good light stability, wide excitation spectrum and controllable emission spectrum, thus the quantum dot has a wide application prospect in photovoltaic power generation, photoelectric display, biological probes and other technical fields.

With more and more in-depth research and development of the quantum dot, conventional quantum dot types are gradually difficult to meet needs of more and more application scenarios. Therefore, it is urgent to develop a new quantum dot to expand quantum dot types.

### TECHNICAL SOLUTION

In view of this, the present disclosure provides a quantum dot and a preparation method thereof, and a photoelectric device.

According to a first aspect, the present disclosure provides a quantum dot with a core-shell structure. In a radial direction, the quantum dot includes a core, a first layer wrapping the core, and a second layer wrapping the first layer disposed sequentially. A band gap of the first layer is less than a band gap of the core, and the band gap of the first layer is less than a band gap of the second layer.

According to a second aspect, the present disclosure provides a method for preparing a quantum dot comprising:

S1. providing a cationic precursor which is a solution comprising a zinc source and a cadmium source, introducing an inert gas at room temperature to expel air, and heating the cationic precursor to a temperature ranged between 125° C. and 180° C. for 30 minutes˜90 minutes to obtain a basic solution, after the air is completely expelled:

S2. heating the basic solution to a reaction temperature, injecting an anionic precursor into the basic solution, and ripening to obtain a core:

S3. forming multiple shell layers sequentially on a surface of the core to obtain a reaction liquid comprising the quantum dot:
wherein the quantum dot with a core-shell structure, and in a radial direction, the quantum dot comprises a core, a first layer wrapping the core, and a second layer wrapping the first layer disposed sequentially: a band gap of the first layer is less than a band gap of the core, and the band gap of the first layer is less than a band gap of the second layer.

According to a third aspect, the present disclosure provides a photoelectric device including:
an anode;
a cathode; and
multiple functional layers disposed between the anode and the cathode, where a material of at least one of the multiple functional layers includes a quantum dot with a core-shell structure. In a radial direction, the quantum dot includes a core, a first layer wrapping the core, and a second layer wrapping the first layer disposed sequentially. A band gap of the first layer is less than a band gap of the core, and the band gap of the first layer is less than a band gap of the second layer.

The quantum dot provided by the present disclosure has a well structure, thereby being beneficial to increase an exciton confinement effect of the quantum dot, bind excitons away from a surface of the quantum dot, avoid excitons being trapped by surface defects, and improve a fluorescence quantum efficiency of the quantum dot.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings might be obtained based on these drawings.

FIG. 1 is a schematic diagram of a first quantum dot according to an embodiment of the present disclosure.

FIG. 2 is a schematic diagram of a second quantum dot according to an embodiment of the present disclosure.

FIG. 3 is a schematic diagram of a third quantum dot according to an embodiment of the present disclosure.

FIG. 4 is a schematic diagram of a photoelectric device according to an embodiment of the present disclosure.

### DETAILED DESCRIPTION

Technical solutions in embodiments of the present disclosure will be clearly and completely described below in conjunction with drawings of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Unless otherwise defined, all professional and scientific terms used herein have same meanings as those familiar to those skilled in the art. Furthermore, any method or any material similar or equivalent to that described might be used in the present disclosure. A preferred embodiment and a preferred material described herein are for illustrative purposes only, but are not intended to limit contents of the present disclosure.

An order of description of the following embodiments is not intended to limit a preferred order of the embodiments.

Each embodiment of the present disclosure may be presented in a form of range. It should be understood that a description in the form of range is merely for convenience and brevity, and should not be construed as a limitation on the scope of the disclosure. Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

In the present disclosure, “including” refers to “including but not limited to”.

In the present disclosure, “at least one” refers to one or more, and “more” in the “one or more” refers to two or more. “one or more”, “at least one of the followings”, or similar expressions thereof refer to any combination of items listed, including any combination of a singular item or multiple items. For example, “at least one of a, b, or c”, or “at least one of a, b, and c”, may each represent: a, b, c, a-b (i.e., a and b), a-c, b-c, or a-b-c, wherein a, b, and c may be single or plural.

In the present disclosure, “and/or” is used to describe an association of associated objects, and means that there may be three relationships, for example, “A and/or B” may refer to three cases: a first case refers to the presence of A alone. A second case refers to the presence of both A and B. A third case refers to the presence of B alone, where A and B may be singular or plural.

In the present disclosure, a description of “the A layer is formed on a side of the B layer” or “the A layer is formed on a side of the B layer away from the C layer” may mean that the A layer is directly formed on the side of the B layer or the side of the B layer away from the C layer, that is, the A layer is in contact with the B layer. It may also mean that the A layer is indirectly formed on the side of the B layer or the side of the B layer away from the C layer, that is, another film layer may be formed between the A layer and the B layer.

In the present disclosure, “particle size” refers to a diameter of a nanoparticle.

In the present disclosure, “conduction band” refers to an energy level of excited electrons in an excited crystal, and a conduction band takes a vacuum energy level of 0 as a reference value. “conduction band minimum” refers to the lowest energy level of a conduction band.

In the present disclosure, “valance band” refers to an energy level of unexcited electrons of a crystal in a ground state, and a valance band takes a vacuum energy level of 0 as a reference value. “valance band maximum” refers to the highest energy level of a valance band.

In the present disclosure, “band gap” refers to a difference between a conduction band minimum and a valance band maximum.

In the present disclosure, a difference between A and B refers to A as a minuend and B as a subtrahend, and the difference is a numerical value obtained by subtracting B from A.

When describing a structural composition of a quantum dot in the present disclosure, each layer is arranged in an order from a core of the quantum dot to an outermost shell layer of the quantum dot. Taking the quantum dot of ZnA/CdM/CdₓZn₍₁₋ₓ₎Z/Cd_{y1}Zn_{(1-y1)}Se/ZnS as an example, ZnA represents a component of a core of the quantum dot, CdM represents a component of a first layer of the quantum dot, CdₓZn₍₁₋ₓ₎Z represents a component of a second layer of the quantum dot, Cd_{y1}Zn_{(1-y1)}Se represents a component of a third layer of the quantum dot, and ZnS represents a component of a fourth layer of the quantum dot.

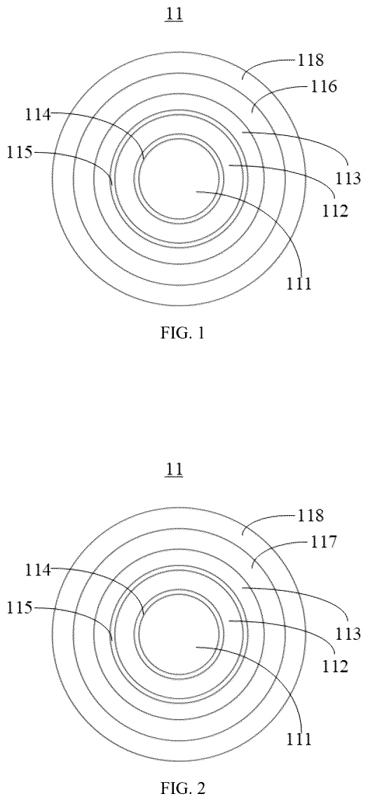

Accordingly, an embodiment of the present disclosure provides a quantum dot with a core-shell structure. Referring to FIGS. 1˜3, in a radial direction, the quantum dot 11 includes a core 111, a first layer 112 wrapping the core 111, and a second layer 113 wrapping the first layer 112 disposed sequentially, where a band gap of the first layer 112 is less than a band gap of the core 111, and the band gap of the first layer 112 is less than a band gap of the second layer 113.

The quantum dot 11 has a well structure. The well structure is beneficial to increase an exciton confinement effect of the quantum dot 11, bind excitons away from a surface of the quantum dot 11, avoid excitons being trapped by surface defects, and improve a fluorescence quantum efficiency of the quantum dot 11.

In order to reduce a difficulty of carriers injection, the band gap of the second layer 113 is less than or equal to the band gap of the core 111.

In some embodiments, the quantum dot 11 is a blue quantum dot.

In order to improve a recombination luminous efficiency of electrons and holes injecting in the quantum dot, in some embodiments, a difference between a valance band maximum of the core 111 and a valance band maximum of the first layer 112 is less than or equal to −0.2 eV, such as less than or equal to −0.22 eV, less than or equal to −0.25 eV, or less than or equal to −0.3 eV, a difference between a conduction band minimum of the core 111 and a conduction band minimum of the first layer 112 is greater than or equal to 0.2 eV, a difference between the valance band maximum of the first layer 112 and a valance band maximum of the second layer 113 is greater than or equal to 0.2 eV, such as greater than or equal to 0.22 eV, greater than or equal to 0.25 eV, greater than or equal to 0.28 eV, or greater than or equal to 0.3 eV, and a difference between the conduction band minimum of the first layer and a conduction band minimum of the second layer is less than or equal to −0.2 eV, such as less than or equal to −0.22 eV, less than or equal to −0.25 eV, or less than or equal to −0.3 eV.

In some embodiments, the difference between the valance band maximum of the core 111 and a valance band maximum of the first layer 112 is greater than or equal to −0.8 eV and less than or equal to −0.2 eV.

In some embodiments, the difference between the valance band maximum of the first layer 112 and the valance band maximum of the second layer 113 is greater than or equal to 0.2 eV and less than or equal to 0.8 eV.

In order to control an emission wavelength of the quantum dot 11 is less than or equal to 475 nm, in some embodiments, an average particle size of the core 111 ranges from 2 nm to 8 nm, such as 2 nm, 4 nm, 6 nm, 8 nm, or a value between any two thereof. An average thickness of the first layer 112 ranges from 1 nm to 3 nm, such as 1 nm, 2 nm, 3 nm, or a value between any two thereof. An average thickness of the second layer 113 ranges from 1 nm to 4 nm, such as 1 nm, 2 nm, 3 nm, 4 nm, or a value between any two thereof. An average particle size of the quantum dot ranges from 4 nm to 15 nm, such as 4 nm, 6 nm, 8 nm, 10 nm, 12 nm, 15 nm, or a value between any two thereof.

In some embodiments, a material of the core 111 is a first compound, a material of the first layer 112 is a second compound, and a material of the second layer is a third compound.

Furthermore, referring to FIGS. 1˜3, the quantum dot 11 further includes a first interfacial fusion layer 114 between the core 111 and the first layer 112. A material of the first interfacial fusion layer 114 includes the first compound and the second compound, and along a radial direction from the core 111 to the first layer 112, a mole percentage of the first compound gradually decreases and a mole percentage of the second compound gradually increases, thereby forming a gradient change energy level which is conducive to further reducing the difficulty of carriers injection. An thickness of the first interfacial fusion layer 114 may range from 0.2 nm to 2 nm, such as 0.2 nm. 0.5 nm, 0.8 nm, 1 nm, 1.5 nm, 2 nm, or a value between any two thereof. The first interfacial fusion layer 114 is mainly derived from an exchange of interfacial atoms. At a specific temperature, the first layer 112 having a different composition from the core 111 is grown on a surface of the core 111, and atomic exchange occurs at an interface between the core 111 and the first layer 112, thereby forming the first interfacial fusion layer 114.

In some embodiments, referring to FIGS. 1˜3, the quantum dot further includes a second interfacial fusion layer 115 between the first layer 112 and the second layer 113. A material of the second interfacial fusion layer 115 includes the second compound and the third compound, and along a radial direction from the first layer 112 to the second layer 113, a mole percentage of the second compound gradually decreases and a mole percentage of the third compound gradually increases, thereby forming a gradient change energy level which is conducive to further reducing the difficulty of carriers injection. An thickness of the second interfacial fusion layer 115 may range from 0.2 nm to 2 nm, such as 0.2 nm, 0.5 nm, 0.8 nm, 1 nm, 1.5 nm, 2 nm, or a value between any two thereof. The second interfacial fusion layer 115 is mainly derived from an exchange of interfacial atoms. At a specific temperature, the second layer 113 having a different composition from the first layer 112 is grown on a surface of the first layer 112, and atomic exchange occurs at an interface between the first layer 112 and the second layer 113, thereby forming the second interfacial fusion layer 115.

In some embodiments, the material of the core 111, the material of the first layer 112, and the material of the second layer 113 each independently include but not limited to one or more of a group II-VI compound, a group IV-VI compound, a group III-V compound, a group III-VI compound, and a group I-III-VI compound. The group II-VI compound includes but not limited to one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound includes but not limited to one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The group III-VI compound includes but not limited to one or more of In₂S₃, In₂Se₃, InGaS₃, and InGaSe₃. The group III-V compound includes but not limited to one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The group I-III-VI compound includes but not limited to one or more of AgInS, AgInS₂, CuInS, CuInS₂, AgGaS₂, CuGaS₂, CuGaO₂, AgGaO₂, AgAlO₂, AgInGaS₂, and CuInGaS₂.

In some embodiments, the material of the core 111 is ZnA, the material of the first layer 112 is CdM, and the material of the second layer 113 is CdₓZn₍₁₋ₓ₎Z, where A, M, and Z are each independently selected from Se or S, and x is greater than or equal to 0.2 and less than or equal to 0.5, such as 0.2, 0.3, 0.4, 0.5, or a value between any two thereof.

In order to further increase an exciton lifetime of the quantum dot 11 and reduce a probability of generating a non-radiative auger recombination, in some embodiments, referring to FIGS. 1˜3, the quantum dot 11 further includes at least one layer wrapping the core 111, the first layer 112, and the second layer 113. At least one layer is selected from one or more of a third layer 116 with a hole confinement structure, a fourth layer 117 with electron confinement structure, and a fifth layer 118 with a Type I confinement structure.

In the radial direction, from the core 111 to the second layer 113 are configured as an integral structure, for example, the integral structure includes the core 111, the first interfacial fusion layer 114, the first layer 112, the second interfacial fusion layer 115, and the second layer 113. An absolute value of a difference between a valance band maximum of the third layer 116 and a valance band maximum of the integral structure is greater than 0 eV and less than or equal to 0.2 eV, such as 0.1 eV, 0.15 eV, 0.18 eV, or a value between any two thereof, and an absolute value of a difference between a conduction band minimum of the integral structure and a conduction band minimum of the third layer 116 is greater than or equal to 0.2 eV and less than or equal to 0.8 eV, such as 0.2 eV, 0.3 eV, 0.4 eV, 0.5 eV, 0.6 eV, 0.7 eV, 0.8 eV, or a value between any two thereof.

In some embodiments, the difference between the valance band maximum of the third layer 116 and the valance band maximum of the integral structure is greater than −0.2 eV and less than 0 eV, and the difference between the conduction band minimum of the integral structure and the conduction band minimum of the third layer 116 is greater than or equal to 0.2 eV and less than or equal to 0.8 eV.

An absolute value of a difference between a valance band maximum of the fourth layer 117 and a valance band maximum of the integral structure is greater than or equal to 0.2 eV and less than or equal to 0.8 eV, such as 0.2 eV. 0.3 eV, 0.4 eV, 0.5 eV, 0.6 eV, 0.7 eV, 0.8 eV, or a value between any two thereof, and an absolute value of a difference between a conduction band minimum of the integral structure and a conduction band minimum of the fourth layer 117 is greater than 0 eV and less than or equal to 0.2 eV, such as 0.1 eV, 0.15 eV, 0.18 eV, or a value between any two thereof.

In some embodiments, the difference between the valance band maximum of the fourth layer 117 and the valance band maximum of the integral structure is greater than or equal to −0.8 eV and less than or equal to −0.2 eV, and the difference between the conduction band minimum of the integral structure and the conduction band minimum of the fourth layer 117 is greater than 0 eV and less than or equal to 0.2 eV.

An absolute value of a difference between a valance band maximum of the fifth layer 118 and a valance band maximum of the integral structure is greater than or equal to 0.2 eV and less than or equal to 0.8 eV, such as 0.2 eV, 0.3 eV, 0.4 eV, 0.5 eV, 0.6 eV, 0.7 eV, 0.8 eV, or a value between any two thereof, and an absolute value of a difference between a conduction band minimum of the integral structure and a conduction band minimum of the fifth layer 118 is greater than or equal to 0.2 eV and less than or equal to 0.8 eV, such as 0.2 eV, 0.3 eV, 0.4 eV, 0.5 eV, 0.6 eV, 0.7 eV, 0.8 eV, or a value between any two thereof.

In some embodiments, the difference between the valance band maximum of the fifth layer 118 and the valance band maximum of the integral structure is greater than or equal to −0.8 eV and less than or equal to −0.2 eV, and the difference between the conduction band minimum of the integral structure and the conduction band minimum of the fifth layer 118 is greater than or equal to 0.2 eV and less than or equal to 0.8 eV.

It should be noted that the valance band maximum and the conduction band minimum of each layer or the integral structure may be obtained by an ultraviolet photo −electron spectroscopy test, respectively.

In order to further improve the fluorescence quantum efficiency and stability of the quantum dot 11, in some embodiments, referring to FIG. 1, the quantum dot 11 includes the third layer 116 and the fifth layer 118, where the fifth layer 118 is an outermost layer of the quantum dot 11, thereby improving a delocalization range of holes and helping to improve a transmission speed of holes. In the embodiments, in the radial direction, the quantum dot 11 includes the core 111, the first layer 112, the second layer 113, the third layer 116, and the fifth layer 118 disposed sequentially: Due to an atomic exchange phenomenon at an interface, there may be a third interfacial fusion layer between the third layer 116 and the second layer 113, and there may be a fourth interfacial fusion layer between the third layer 116 and the fifth layer 118.

In order to further improve the fluorescence quantum efficiency and stability of the quantum dot 11, in some embodiments, referring to FIG. 2, the quantum dot 11 includes the fourth layer 117 and the fifth layer 118, where the fifth layer 118 is an outermost layer of the quantum dot, thereby improving a delocalization range of electrons and helping to improve a transmission speed of electrons. In the embodiments, in the radial direction, the quantum dot 11 includes the core 111, the first layer 112, the second layer 113, the fourth layer 117, and the fifth layer 118 disposed sequentially. Due to an atomic exchange phenomenon at an interface, there may be a fifth interfacial fusion layer between the fourth layer 117 and the second layer 113, and there may be a sixth interfacial fusion layer between the fourth layer 117 and the fifth layer 118.

In order to further improve the fluorescence quantum efficiency and stability of the quantum dot 11, in some embodiments, the quantum dot 11 includes the third layer 116, the fourth layer 117, and the fifth layer 118, where the fourth layer is disposed between the third layer and the fifth layer or the third layer is disposed between the fourth layer and the fifth layer. By fully delocalizing holes and electrons, an overlap between a wave function of holes and a wave function of electrons is reduced, an exciton lifetime of the quantum dot is improved, a risk of surface defect state quenching of the quantum dot is reduced, and a radiation recombination efficiency is improved.

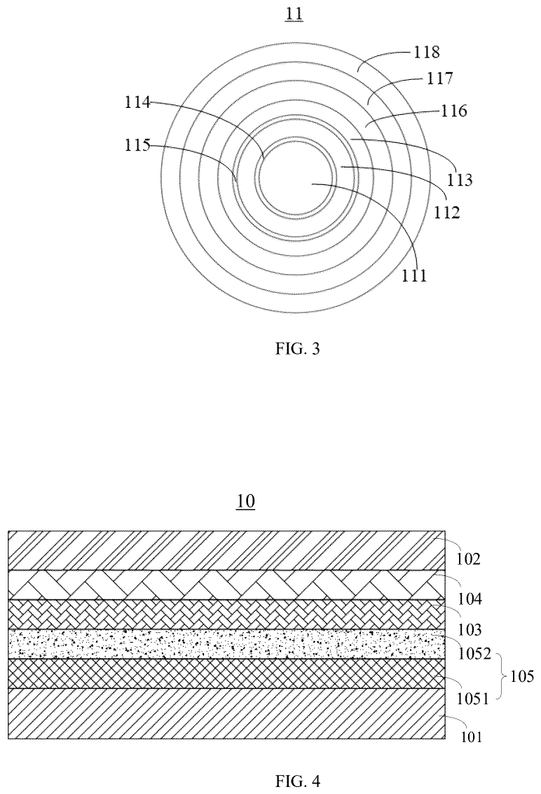

In some embodiments, in the radial direction, referring to FIG. 3, the quantum dot 11 includes the core 111, the first layer 112, the second layer 113, the third layer 116, the fourth layer 117, and the fifth layer 118 disposed sequentially. Due to the atomic exchange phenomenon at the interface, there may be the third interfacial fusion layer between the third layer 116 and the second layer 113, there may be a seventh interfacial fusion layer between the third layer 116 and the fourth layer 117, and there may be a sixth interfacial fusion layer between the fourth layer 117 and the fifth layer 118.

In other embodiments, in the radial direction, the quantum dot 11 includes the core 111, the first layer 112, the second layer 113, the fourth layer 117, the third layer 116, and the fifth layer 118 disposed sequentially. Due to the atomic exchange phenomenon at the interface, there may be the fifth interfacial fusion layer between the fourth layer 117 and the second layer 113, and there may be an eighth interfacial fusion layer between the fourth layer 117 and the third layer 116, and there may be the fourth interfacial fusion layer between the third layer 116 and the fifth layer 118.

In some embodiments, the quantum dot 11 is configured as a light-emitting material of a quantum dot light-emitting diode. Since the quantum dot light-emitting diode has a problem that an electron injection level is much larger than an hole injection level, especially in a blue quantum dot light-emitting diode, a shell of the quantum dot is formed of the third layer 116, the fourth layer 117, and the fifth layer 118, and the third layer 116 is disposed between the fourth layer 117 and the fifth layer 118, thereby having a greater influence on limiting a delocalization of the electron wave function, and promoting an electron-hole transport balance.

In some embodiments, a material of the third layer 116 is Cd_{y1}Zn_{(1-y1)}Se, where y1 is greater than or equal to 0 and less than 1. An average thickness of the third layer 116 may range from 1 nm to 3 nm.

In some embodiments, a material of the fourth layer 117 is Cd_{y2}Zn_{(1-y2)}S, where y2 is greater than 0 and less than or equal to 1. An average thickness of the fourth layer 117 may range from 1 nm to 3 nm.

In some embodiments, a material of the fifth layer 118 is ZnS, and an average thickness of the fifth layer 118 may range from 0.5 nm to 2 nm.

In some embodiments, an average thickness of the shell of the quantum dot 11 range from 2.5 nm to 8 nm, such as 2.5 nm, 3 nm, 4 nm, 5 nm, 6 nm, 7 nm, 8 nm, or a value between any two thereof.

In some embodiments, a general structure of the quantum dot is ZnA/CdM/CdₓZn₍₁₋ₓ₎Z/Cd_{y1}Zn_{(1-y1)}Se/Cd_{y2}Zn_{(1-y2)}S/ZnS, ZnA/CdM/CdₓZn₍₁₋ₓ₎Z/Cd_{y1}Zn_{(1-y1)}Se/ZnS, or ZnA/CdM/CdₓZn₍₁₋ₓ₎Z/Cd_{y2}Zn_{(1-y2)}S/ZnS, where A, M, and Z are each independently selected from Se or S, x is greater than or equal to 0.2 and less than or equal to 0.5, y1 is greater than or equal to 0 and less than 1, and y2 is greater than 0 and less than or equal to 1. For example, y1 is selected from 0, 0.2, 0.4, 0.6, 0.8, 0.9, 0.95, or a value between any two thereof, and y2 is selected from 0.05, 0.1, 0.2, 0.4, 0.6, 0.8, 1, or a value between any two thereof.

In order to improve the stability and solution processability of the quantum dot 11, in some embodiments, a ligand is attached to the surface of the quantum dot 11. The ligand may be a ligand known in the art, including but not limited to one or more of a C1˜C30 aliphatic carboxylic acid ligand, a C6˜C30 aromatic carboxylic acid ligand, a C1˜C30 aliphatic thiol ligand, a C6˜C30 aromatic thiol ligand, a C1˜C30 aliphatic amine ligand, a C6˜C30 aromatic amine ligand, a C1˜C30 aliphatic phosphine ligand, a C6˜C30 aromatic phosphine ligand, a C6˜C30 aromatic phosphate ester ligand, and a halogen ligand.

The C1˜C30 aliphatic carboxylic acid ligand includes but not limited to one or more of octanoic acid, nonanoic acid, decanoic acid, undecanoic acid, dodecanoic acid, tetradecanoic acid, hexadecanoic acid, octadecanoic acid, eicosanoic acid, tetracosanoic acid, hexacosanoic acid, oleic acid, linoleic acid, arachidic acid, arachidonic acid, erucic acid and docosahexaenoic acid. The C6˜C30 aromatic carboxylic acid ligand includes but not limited to one or more of benzoic acid, bibenzoic acid, and 1-naphthoic acid. The C1˜C30 aliphatic thiol ligand includes but not limited to one or more of hexanethiol, octanethiol, nonanethiol, decanethiol, undecanethiol, dodecanethiol, hexadecanethiol, and octadecanethiol. The C6˜C30 aromatic thiol ligand includes but not limited to one or more of thiophenol, triphenylmethyl mercaptan, and p-terphenyl-4,4″-dithiol. The C1˜C30 aliphatic amine ligand includes but not limited to one or more of hexylamine, octylamine, dioctylamine, trioctylamine, nonylamine, decylamine, dodecylamine, tridecylamine, tetradecylamine, pentadecylamine, hexadecylamine, heptadecylamine, octadecylamine, and oleylamine. The C6˜C30 aromatic amine ligand includes but not limited to one or more of aniline, aprindine, 4-octylaniline, and benzidine. The aliphatic phosphine ligand includes but not limited to one or more of trimethylphosphine, triethylphosphine, tripropylphosphine, tributylphosphine, trihexylphosphine, trioctylphosphine, tridecylphosphine, tributylphosphine oxide, trihexylphosphine oxide, trioctylphosphine oxide, and tridecylphosphine oxide. The C6˜C30 aromatic phosphine ligand includes but not limited to one or more of bis[2-(diphenylphosphino) ethyl]phenylphosphine and triphenylphosphine oxide. The C6˜C30 aromatic phosphate ester ligand includes but not limited to one or more of p-xylylenediphosphonic acid tetraethyl ester and diphenylphosphinic acid ethyl ester. The halogen ligand includes but not limited to one or more of —Cl, —F, —I, and —Br.

In order to further improve the stability of the quantum dot 11, when the outermost layer of the quantum dot 11 includes sulfur, for example, a material of the outermost layer of the quantum dot is ZnS, a sulfur-containing anion source easily decomposed by heating may be used to prepare the outermost layer, where a temperature of the heating ranges from 120° C.˜250° C. The sulfur-containing anion source may be selected from one or more of a C1˜C30 aliphatic thiol compound, diethyldithiocarbamate salt, diethyldithiocarbamate salt, ethylxanthate salt, and hexadecyl xanthate salt. An alkane chain anion source including sulfur is generated by a self-decomposition of the sulfur-containing anion source decomposing. The outermost layer may be formed by a reaction of the alkane chain anion source and a cation source, and a retained alkane chain (e.g., C1˜C30 chain alkyl group) is tightly attached to the surface of the quantum dot 11.

It might be understood that the quantum dot described above may be synthesized by a conventional thermal injection method. For example, a method for preparing the quantum dot includes steps S1˜S3.

In step S1, a cationic precursor which is a solution including a zinc source and a cadmium source is provided, an inert gas is introduced at room temperature to expel air, and after the air is completely expelled, the cationic precursor is heated to a temperature ranged between 125° C. and 180° C. for 30 minutes˜90 minutes to obtain a basic solution. The cationic precursor is contained in a container.

In step S2, the basic solution is heated to a reaction temperature, and an anionic precursor is quickly injected into the basic solution so that a nucleus is formed instantaneously, and the nucleus is ripened at a constant temperature to obtain the core.

In step S3, multiple shell layers are sequentially formed on a surface of the core to obtain a reaction liquid including the quantum dot.

Specifically, in step S1, the zinc source includes but not limited to one or more of zinc oleate, zinc stearate, zinc dodecanoate, zinc tetradecanoate, zinc hexadecanoate, zinc palmitate, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, and zinc sulfate. The cadmium source includes but not limited to one or more of cadmium oxide, cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

In step S1, a solvent of the cationic precursor includes but not limited to one or more of 1-octadecene, paraffin oil, diphenyl ether, dioctyl ether, oleic acid, stearic acid, palmitic acid, and olive oil. For example, the solvent of the cationic precursor consists of oleic acid and 1-octadecene. In order to improve a synthesis yield of the quantum dot and improve a mixing efficiency of the cationic precursor and the anionic precursor, in some embodiments, a volume ratio of oleic acid to 1-octadecene is 1:(1˜5).

In order to both improve the synthesis yield of the quantum dot and a solution processing performance of the cationic precursor, in some embodiments, a concentration of zinc in the cationic precursor ranges from 0.05 mol/L to 1 mol/L.

The inert gas includes but not limited to one or more of nitrogen, argon, helium, neon, krypton, and xenon. A flow rate of the inert gas ranges from 50 mL/minute to 300 mL/minute, and for example, the time of expelling air ranges from 10 minutes to 30 minutes.

In step S1, the anionic precursor may be a selenium precursor and/or a sulfur precursor. The selenium precursor is selected from at least one of Se-TOP, Se-TBP, Se-TPP. Se-ODE, Se-OA, Se-ODA, Se-TOA, Se-ODPA, Se-OLA, Se-OCA, and Se-DPP. The sulfur precursor is selected from at least one of S-TOP, S-TBP. S-TPP. S-ODE, S-OA. S-ODA, S-TOA, S-ODPA, S-OLA, S-OCA, S-DPP, mercaptopropylsilane, and alkyl mercaptans.

In step S2, a speed of injecting the anionic precursor ranges from 1 mmol/minute to 5 mmol/minute.

In step S3, in order to improve the quality of layers, in a process of preparing multiple layers, for example, a speed of injecting the anionic precursor ranges from 1 mmol/minute to 5 mmol/minute.

In order to improve a purity of the quantum dot, after step S3, a reaction product including the quantum dot may be separated and purified by a conventional method to obtain a purified quantum dot.

An embodiment of the present disclosure provides a photoelectric device. The photoelectric device includes but not limited to a light-emitting device, a solar cell or a photodetector. Referring to FIG. 3, the photoelectric device 10 includes an anode 101, a cathode 102, and multiple functional layers disposed between the anode 101 and the cathode 102. A material of at least one of the multiple functional layers includes any one quantum dot of the present disclosure described above, thereby improving a device efficiency and a device lifetime of the photoelectric device 10.

In some embodiments, referring to FIG. 3, the functional layers include a light emitting layer 103 including the quantum dot of the present disclosure described above. For example, a luminescence colour of the quantum dot is blue.

In some embodiments, the anode 101 and the cathode 102 are each independently selected from one or more of a metal, a carbon material, and a first metal oxide. The metal includes but not limited to one or more of Al, Ag, Cu, Mo, Au, Ba, Pt, Ca, Ir, Ni, and Mg, the carbon material includes but not limited to one or more of graphite, carbon nanotube, graphene, and carbon fiber, and the second metal oxide includes but not limited to one or more of indium tin oxide (ITO), fluorine-doped tin oxide (FTO), antimony tin oxide (ATO), aluminium-doped zinc oxide (AZO), gallium-doped zinc oxide (GZO), indium-doped zinc oxide (IZO), magnesium-doped zinc oxide (IZO), SnO₂, ZnO, and In₂O₃.

Each of the anode 101 and the cathode 102 may also be a composite electrode which has a sandwich-like structure. Each of a material of an upper layer and a material of a bottom layer is the first metal oxide, and a material of an intermediate layer is the metal. For example, the composite electrode is selected from one or more of AZO/Ag/AZO, AZO/Al/AZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂. An average thickness of the intermediate layer does not exceed 35 nm. An average thickness of the anode 101 may range from 20 nm to 300 nm, and an average thickness of the cathode 102 may range from 20 nm to 300 nm.

In some embodiments, referring to FIG. 3, the functional layers further include an electron functional layer 104 disposed between the cathode 102 and the light emitting layer 103. The electron functional layer 104 may have a single-layer structure or a multi-layers structure, and an average thickness of the electron functional layer 104 may range from 10 nm to 100 nm. For example, the electron functional layer 104 includes one or more of an electron injection layer, an electron transport layer, and a hole blocking layer.

In one embodiment, the electron functional layer 104 includes the electron injection layer, the electron transport layer, and the hole blocking layer disposed in stack, the electron transport layer is disposed between the electron injection layer and the hole blocking layer, and the electron injection layer is closer to the cathode 102 than the hole blocking layer.

In another embodiment, the electron functional layer 104 includes the electron transport layer and the hole blocking layer disposed in stack. The electron transport layer is closer to the cathode 102 than the hole blocking layer.

In another embodiment, the electron functional layer 104 includes the electron injection layer and the electron transport layer disposed in stack. The electron injection layer is closer to the cathode 102 than the electron transport layer.

A material of the electron functional layer 104 includes one or more of an undoped-type second metal oxide, a group IIB-VIA semiconductor material, and a doped-type third metal oxide. The undoped-type second metal oxide is selected from one or more of ZnO, TiO₂, and SnO₂. The group IIB-VIA semiconductor material includes one or more of ZnS. ZnSe, and CdS.

The third metal oxide material includes a doped-type metal oxide, a doping element of the doped-type metal oxide is selected from one or more of Mg, Ca, Zr, W, Ga, Li, Al, Ti, Y, In, and Sn, and a host compound of the doped-type metal oxide is selected from ZnO, TiO₂, or SnO₂. A host material of the doped-type third metal oxide is selected from ZnO, TiO₂, or SnO₂, and a doping element of the doped-type third metal oxide includes but not limited to one or more of Mg, Ca, Zr, W, Ga, Li, Al, Ti, Y, In, and Sn.

In some embodiments, the doped-type third metal oxide includes but not limited to one or more of magnesium zinc oxide, calcium zinc oxide, zirconium zinc oxide, gallium zinc oxide, aluminum zinc oxide, lithium zinc oxide, titanium zinc oxide, yttrium zinc oxide, indium tin oxide, and lithium titanium oxide. For example, the doped-type third metal oxide is selected from one or more of Zn₍₁₋ₓ₎MgₓO, Zn₍₁₋ₓ₎CaₓO, Zn₍₁₋ₓ₎ZrₓO, Zn₍₁₋ₓ₎GaₓO, Zn(₍₁₋ₓ₎AlₓO, Zn₍₁₋ₓ₎LiₓO, Zn₍₁₋ₓ₎TiₓO, Zn₍₁₋ₓ₎YₓO, In₍₁₋ₓ₎SnₓO, and Ti₍₁₋ₓ₎LiₓO, where x is greater than 0 and less than or equal to 0.5.

Under a condition that the electron functional layer 104 includes multiple materials and the electron functional layer 104 has the multi-layers structure, the multiple materials may all be in the same layer, or may be in different layers, or may be partially in the same layer.

In some embodiments, referring to FIG. 3, the functional layers further include a hole functional layer 105 disposed between the anode 101 and the light emitting layer 103. The hole functional layer 105 may have a single-layer structure or a multi-layers structure, and an average thickness of the hole functional layer 105 may range from 10 nm to 100 nm. For example, the hole functional layer 105 includes one or more of a hole injection layer, a hole transport layer, and an electron blocking layer.

In one embodiment, the hole functional layer 105 includes the hole injection layer, the hole transport layer, and the electron blocking layer disposed in stack, the hole transport layer is disposed between the hole injection layer and the electron blocking layer, and the hole injection layer is closer to the anode 101 than the electron blocking layer.

In another embodiment, the hole functional layer 105 includes the hole transport layer and the electron blocking layer disposed in stack. The hole transport layer is closer to the anode 101 than the electron blocking layer.

In another embodiment, the hole functional layer 105 includes the hole injection layer and the hole transport layer disposed in stack. The hole injection layer is closer to the anode 101 than the hole transport layer.

A material of the hole functional layer 105 includes but not limited to one or more of an organic compound, a first inorganic compound, and a second inorganic compound. The organic compound includes but not limited to one or more of poly(3,4-ethylenedioxythiophene)-poly(styrenesulfonate) (PEDOT:PSS, CAS: 155090-83-8), copper (II) phthalocyanine (CAS: 147-14-8), titanyl phthalocyanine (CAS: 26201-32-1), 2,3,5,6-tetrafluoro-7,7,8,8-tetracyanoquinodimethane (CAS: 29261-33-4), hexaazatriphenylenehexacabonitrile (CAS: 105598-27-4), polyaniline (CAS: 25233-30-1), polypyrrole (CAS: 30604-81-0), poly(3-hexylthiophene-2,5-diyl) (CAS: 104934-50-1), poly(n-vinylcarbazole)(PVK, CAS: 25067-59-8), 4,4′-Bis(N-carbazolyl)-1,1′-biphenyl (CBP. CAS: 58328-31-7), poly[N,N′-bis(4-butylphenyl)-N,N′-bis(phenyl)-benzi (CAS: 472960-35-3), 4,4′-cyclohexylidenebis[N,N-bis(4-methylphenyl)aniline] (TAPC, CAS: 58473-78-2), poly(9,9-dioctylfluorene-co-N-(4-butylphenyl)diphenylamine) (TFB, CAS: 220797-16-0), poly[(9,9-dioctylfluorenyl-2.7-diyl)-alt-(4,4′-(N-(4-butylphenyl) (CAS: 223569-31-1), 4,4′,4″-tris(N-3-methylphenyl-N-phenylamino)triphenylamine (CAS: 124729-98-2), 4,4′,4″-tris(carbazol-9-yl)-triphenylamine(TCTA, CAS: 139092-78-7), 4.4′,4″-tris[2-naphthyl(phenyl) amino] triphenylamine (CAS: 185690-41-9), N,N′-bis-(1-naphthalenyl)-N,N′-bis-phenyl-(1,1′-biphenyl)-4,4′-diamine (NPB, CAS: 123847-85-8), N,N′-bis(3-methylphenyl)-N,N′-diphenyl-benzidine (TPD, CAS: 65181-78-4), N.N′-bis[4-(diphenylamino)phenyl]-N,N′-diphenylbenzidine (CAS: 209980-53-0), N2,N7-diphenyl-N2,N7-di-m-tolyl-9,9′-spirobi[fluorene]-2,7-diamine (Spiro-TPD, CAS: 1033035-83-4), N2,N7-di-1-naphthalenyl-N2, N7-diphenyl-9,9′-spirobi[9h-fluorene]-2,7-diamine (CAS: 932739-76-9), poly[bis(4-phenyl)(2,4,6-trimethylphenyl)amine] (PTTA, CAS: 1333317-99-9), and 2,2′,7,7′-Tetrakis[N,N-di(4-methoxyphenyl)amino]-9,9′-spirobifluorene (Spiro-omeTAD, CAS: 207739-72-8).

The first inorganic compound includes but not limited to one or more of graphene. C60, nickel oxide, molybdenum oxide, tungsten oxide, vanadium oxide, p-type gallium nitride, chromium oxide, copper oxide, copper sulfide, molybdenum sulfide, and tungsten sulphide.

The second inorganic compound includes at least one doped-type second inorganic compound. A host compound of the doped-type second inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, or tungsten sulphide, a doping element of the doped-type second inorganic compound is selected from one or more of nickel, molybdenum, tungsten, vanadium, chromium, copper and platinum group metal elements, and a ratio of a molar amount of the doping element to a total molar amount of the doped-type second inorganic compound does not exceed 50%.

Under a condition that the hole functional layer 105 includes multiple materials and the hole functional layer 105 has the multi-layers structure, the multiple materials may all be in the same layer, or may be in different layers, or may be partially in the same layer. For example, referring to FIGS. 1˜3, the hole functional layer 105 is formed of the hole injection layer and the hole transport layer disposed in stack. The material of the hole functional layer 105 includes poly(3,4-ethylenedioxythiophene)-poly(styrenesulfonate) (PEDOT:PSS) and poly(9,9-dioctylfluorene-co-N-(4-butylphenyl) diphenylamine) (TFB), PEDOT:PSS and poly(9,9-dioctylfluorene-co-N-(4-butylphenyl) diphenylamine) are in different layers, a material of the hole injection layer is PEDOT:PSS, and a material of the hole transport layer is TFB.

The photoelectric device 10 may further include a substrate disposed on one side of a bottom electrode away from the multiple functional layers. The substrate may be a rigid substrate or a flexible substrate. A material of the rigid substrate includes but not limited to one or more of glass, ceramic, and silicon wafer, and a material of the flexible substrate includes but not limited to one or more of polyimide, polycarbonate, polymethyl methacrylate, polyethylene terephthalate, polyethylene naphthalate, and polyethersulfone.

A method for preparing each functional layer in the photoelectric device 10 includes but not limited to a chemical method and/or a physical method. The chemical method includes but not limited to one or more of a chemical vapor deposition method, a continuous ion layer adsorption and reaction method, an anodic oxidation method, an electrolytic deposition method, and a co-precipitation method. The physical method includes but not limited to a physical coating method and a solution method. The physical coating method includes but not limited to one or more of a thermal evaporation coating method, an electron beam evaporation coating method, a magnetron sputtering method, a multi-arc ion coating method, a physical vapor deposition method, an atomic layer deposition method, and a pulsed laser deposition method. The solution method includes but not limited to one or more of a spin coating method. a printing method, an ink jet printing method, a blade coating method, a dip coating method, a roll coating method, a casting method, a slit coating method, and a strip coating method.

After all functional layers of the photoelectric device having been prepared, an encapsulating step is performed. The encapsulating step may be a commonly used machine encapsulating or a manually encapsulating. In the encapsulating environment, a content of oxygen and a content of water are both lower than 0.1 ppm to ensure a stability of the photoelectric device. Specifically, an encapsulation material used to form an encapsulation layer is selected from one or more of an UV adhesive, a metal film, and a glass adhesive, as an example, the encapsulation material is an acrylic resin or an epoxy resin.

An embodiment of the present disclosure provides an electronic apparatus including the photoelectric device according to any one of the embodiments of the present disclosure. The electronic device may be any electronic product with a display function, including but not limited to a smartphone, a tablet personal computer, a notebook computer, a video telephone, an electronic book reader, a laptop personal computer, a netbook computer, a workstation, a server, a personal digital assistant, a portable multimedia player, a mobile medical machine, a camera, a game console, a car navigation, an electronic billboard, a smart wearable device, or a virtual reality device. The smart wearable device may be, for example, a smart bracelet, a smart watch, or the like.

In the following, the present disclosure is specifically described by specific embodiments, and the following examples are only partial examples of the present disclosure, and the present disclosure is not limited thereto.

In a method for preparing a zinc oleate solution, 10 mmol of zinc acetate, 10 mL of oleic acid, and 20 mL of 1-octadecene were sequentially added into a 100 mL three-neck flask, and an argon gas was introduced at room temperature with a flow rate of 100 mL/min. After expelling air for 15 minutes, the zinc oleate solution was obtained after heating at 150° C. under an argon atmosphere for 60 minutes.

In a method for preparing a cadmium oleate solution, 5 mmol of cadmium oxide, 5 mL of oleic acid, and 20 mL of 1-octadecene were sequentially added into a 100 mL three-neck flask, and an argon gas was introduced at room temperature with a flow rate of 100 mL/min. After expelling air for 15 minutes, the cadmium oleate solution was obtained after heating at 150° C. for 60 minutes and then heating at 240° C. for 30 minutes.

In a method for preparing a S-TOP solution, 5 mmol of sulfur powder and 5 mL TOP were sequentially added into a 50 mL three-neck flask, and an argon gas was introduced at room temperature with a flow rate of 50 mL/min. After expelling air for 15 minutes, the S-TOP solution was obtained after heating at 100° C. while stirring under an argon atmosphere until the sulfur powder was completely dispersed.

In a method for preparing a Se-TOP solution, 5 mmol of selenium powder and 5 mL TOP were sequentially added into a 50 mL three-neck flask, and an argon gas was introduced at room temperature with a flow rate of 50 mL/min. After expelling air for 15 minutes, the Se-TOP solution was obtained after heating at 150° C. while stirring under an argon atmosphere until the selenium powder was completely dispersed.

A method for preparing a Zn (DDTC) 2 solution includes step S1.1 and step S1.2.

In step S1.1, a first solution was obtained by dissolving 20 mmol of sodium diethyldithiocarbamate (NaDDTC) in 60 mL of deionized water with stirring, and a second solution was obtained by dissolving 10 mmol of zinc acetate dehydrate in 100 mL of deionized water with stirring, then the first solution was added dropwise to the second solution, after mixing for 2 hours, a solid-liquid separation was performed to collect a white precipitate. After washing the white precipitate several times with deionized water, anhydrous zinc acetate was obtained by drying in a vacuum drying oven at room temperature for 24 h.

In step S1.2, 10 mL of oleylamine, 20 mL of 1-octadecene, and 15 mmol of the anhydrous zinc acetate were added into a 100 mL three-neck flask, after heating at 100° C. for 30 minutes to remove water and oxygen. 5 mmol of zinc bis(diethyldithiocarbamate) was added at 25° C., and the Zn(DDTC)₂ solution was obtained by heating at 60° C. for 30 minutes.

### Example 1

The present embodiment provides a quantum dot and a preparation method thereof. The quantum dot is a blue quantum dot. Referring to FIG. 3, in the radial direction, the quantum dot 11 includes the core 111, the first layer 112 wrapping the core 111, and the second layer 113 wrapping the first layer 112 disposed sequentially. The material of the core 111 is ZnS, and the average particle size of the core 111 is 3 nm. The material of the first layer 112 is CdSe, and the average thickness of the first layer 112 is 1 nm. The material of the second layer 113 is Cd_{0.2}Zn_{0.8}Se, and the average thickness of the second layer 113 is 2 nm. There is the first interface fusion layer 114 between the core 111 and the first layer 112, where along the radial direction from the core 111 to the first layer 112, a mole percentage of ZnS gradually decreases and a mole percentage of CdSe gradually increases, thereby forming an interface with a gradient change energy level. There is the second interfacial fusion layer 115 between the first layer 112 and the second layer 113, where along the radial direction from the first layer 112 to the second layer 113, a mole percentage of CdSe gradually decreases and a mole percentage of Cd_{0.2}Zn_{0.8}Se gradually increases, thereby forming an interface with a gradient change energy level.

Referring to FIG. 3, in the radial direction, the quantum dot 11 further includes the third layer 116, the fourth layer 117 wrapping the third layer 116, and the fifth layer 118 wrapping the fourth layer 117. The fifth layer 118 is the outermost layer of the quantum dot 11. The material of the third layer 116 is ZnSe, and the average thickness of the third layer 116 is 1.5 nm. The material of the fourth layer 117 is CdS, and the average thickness of the fourth layer 117 is 1 nm. The material of the fifth layer 118 is ZnS, and the average thickness of the fifth layer 118 is 0.5 nm.

In the radial direction, from the core 111 to the second layer 113 are configured as an integral structure. The integral structure is formed of the core 111, the first interfacial fusion layer 114, the first layer 112, the second interfacial fusion layer 115, and the second layer 113.

The difference between the valance band maximum of the third layer 116 and the valance band maximum of the integral structure is −0.1 eV, and the difference between the conduction band minimum of the integral structure and the conduction band minimum of the third layer 116 is 0.3 eV.

The difference between the valance band maximum of the fourth layer 117 and the valance band maximum of the integral structure is −0.3 eV, and the difference between the conduction band minimum of the integral structure and the conduction band minimum of the fourth layer 117 is 0.1 eV.

The difference between the valance band maximum of the fifth layer 118 and the valance band maximum of the integral structure is −0.4 eV, and the difference between the conduction band minimum of the integral structure and the conduction band minimum of the fifth layer 118 is 0.35 eV.

A method for preparing the quantum dot of the present embodiment includes steps S10˜S60.

In step S10, 20 mL of the zinc oleate solution was added into a three-necked flask, after heating the zinc oleate solution to 310° C., 1 mL of the S-TOP solution was injected into the zinc oleate solution, and a first solution including the core was obtained by ripening for 20 minutes.

In step S20, a mixture consisting of 1 mL of the Se-TOP solution and 5 mL of the cadmium oleate solution was injected into the first solution at 310° C. with a rate of 12 mL/h, and a second solution including the core, the first interface fusion layer, and the first layer was obtained by a mixing reaction for 20 minutes.

In step S30, a mixture consisting of 1 mL of the Se-TOP solution and 1 mL of the cadmium oleate solution was injected into the first solution at 310° C. with a rate of 6 mL/h, and a third solution including the core, the first interface fusion layer, the first layer, the second interfacial fusion layer, and the second layer was obtained by a mixing reaction for 20 minutes.

In step S40, 2 mL of the Se-TOP solution was injected into the third solution at 300° C. with a rate of 8 mL/h to form the third layer, then a mixture consisting of 0.5 mL of the S-TOP solution and 2.5 mL of the cadmium oleate solution was added with a rate of 10 mL/h, and the fourth solution including the core, the first interface fusion layer, the first layer, the second interfacial fusion layer, the second layer, the third layer, and the fourth layer was obtained by a reaction.

In step S50, 0.5 mL of 1-dodecanethiol was injected into the fourth solution at 150° C., and a product including the quantum dot was obtained by a reaction for 10 minutes.

In step S60, 40 mL of n-hexane and 40 mL of ethyl acetate were added into a centrifuge tube, then the product including the quantum dot and 60 mL of ethanol were sequentially added into the centrifuge tube, after shaking evenly, the centrifuge tube was centrifuged at 10000 r/min for 5 minutes, and a first precipitate was obtained after removing a supernatant. Subsequently, the first precipitate was re-dissolved with 30 mL of n-hexane, then 15 mL of ethanol was added, after shaking evenly, the centrifuge tube was centrifuged at 10000 r/min for 5 minutes, finally, a second precipitate which was a purified quantum dot was obtained after removing a supernatant.

### Example 2

The present embodiment provides a quantum dot and a preparation method thereof. Compared with the quantum dot in Example 1, the quantum dot in the present embodiment is different in that the material of the second layer is Cd_{0.5}An_{0.5}Se, and correspondingly, “Cd_{0.2}Zn_{0.8}Se” in the second interface fusion layer is replaced with “Cd_{0.2}Zn_{0.8}Se”.

Compared with the method for preparing the quantum dot in Example 1, a method for preparing the quantum dot in the present embodiment is different in that step S20 is replaced with “a mixture consisting of 1 mL of the Se-TOP solution and 0.25 mL of the cadmium oleate solution was injected into the first solution at 310° C. with a rate of 12 mL/h, and a second solution including the core, the first interface fusion layer, and the first layer was obtained by a mixing reaction for 20 minutes”.

### Example 3

The present embodiment provides a quantum dot and a preparation method thereof. Compared with the quantum dot in Example 1, the quantum dot in the present embodiment is different in that the fourth layer is omitted.

Compared with the method for preparing the quantum dot in Example 1, a method for preparing the quantum dot in the present embodiment is different in that step S40 is replaced with “2 mL of the Se-TOP solution was injected into the third solution at 300° C. with a rate of 8 mL/h, and the fourth solution including the core, the first interface fusion layer, the first layer, the second interfacial fusion layer, the second layer, and the third layer was obtained by a reaction”.

### Example 4

The present embodiment provides a quantum dot and a preparation method thereof. Compared with the quantum dot in Example 1, the quantum dot in the present embodiment is different in that the third layer is omitted.

Compared with the method for preparing the quantum dot in Example 1, a method for preparing the quantum dot in the present embodiment is different in that step S30 is replaced with “a mixture consisting of 0.5 mL of the S-TOP solution and 2.5 mL of the cadmium oleate solution was injected into the third solution at 300° C. with a rate of 10 mL/h, and the fourth solution including the core, the first interface fusion layer, the first layer, the second interfacial fusion layer, the second layer, and the fourth layer was obtained by a reaction”.

### Example 5

The present embodiment provides a quantum dot and a preparation method thereof. Compared with the quantum dot in Example 1, the quantum dot in the present embodiment is different in that the fifth layer is prepared by S-TOP.

Compared with the method for preparing the quantum dot in Example 1, a method for preparing the quantum dot in the present embodiment is different in that step S50 is replaced with “0.5 mL of the S-TOP solution was injected into the fourth solution at 150° C., and a product including the quantum dot was obtained by a reaction for 10 minutes”.

### Example 6

The present embodiment provides a quantum dot and a preparation method thereof. The quantum dot is a blue quantum dot. Referring to FIG. 3, in the radial direction, the quantum dot 11 includes the core 111, the first layer 112 wrapping the core 111, and the second layer 113 wrapping the first layer 112 disposed sequentially. The material of the core 111 is ZnSe, and the average particle size of the core 111 is 6 nm. The material of the first layer 112 is CdSe, and the average thickness of the first layer 112 is 1 nm. The material of the second layer 113 is Cd_{0.5}Zn_{0.5}S, and the average thickness of the second layer 113 is 1 nm. There is the first interface fusion layer 114 between the core 111 and the first layer 112, where along the radial direction from the core 111 to the first layer 112, a mole percentage of ZnSe gradually decreases and a mole percentage of CdSe gradually increases, thereby forming an interface with a gradient change energy level. There is the second interfacial fusion layer 115 between the first layer 112 and the second layer 113, where along the radial direction from the first layer 112 to the second layer 113, a mole percentage of CdSe gradually decreases and a mole percentage of Cd_{0.5}Zn_{0.5}S gradually increases, thereby forming an interface with a gradient change energy level.

Referring to FIG. 3, in the radial direction, the quantum dot 11 further includes the third layer 116, the fourth layer 117 wrapping the third layer 116, and the fifth layer 118 wrapping the fourth layer 117. The fifth layer 118 is the outermost layer of the quantum dot 11. The material of the third layer 116 is CdZnSe, and the average thickness of the third layer 116 is 1 nm. The material of the fourth layer 117 is CdZnS, and the average thickness of the fourth layer 117 is 0.5 nm. The material of the fifth layer 118 is ZnS, and the average thickness of the fifth layer 118 is 0.25 nm.

A method for preparing the quantum dot of the present embodiment includes steps S100˜S600.

In step S100, 15 mL of the zinc oleate solution was added into a three-necked flask, after heating the zinc oleate solution to 310° C., 1 mL of the Se-TOP solution was injected into the zinc oleate solution, and a first solution including the core was obtained by ripening for 20 minutes.

In step S200, a mixture consisting of 1 mL of the Se-TOP solution and 5 mL of the cadmium oleate solution was injected into the first solution at 310° C. with a rate of 12 mL/h, and a second solution including the core, the first interface fusion layer, and the first layer was obtained by a mixing reaction for 20 minutes.

In step S300, a mixture consisting of 1 mL of the S-TOP solution and 2.5 mL of the cadmium oleate solution was injected into the first solution at 310° C. with a rate of 12 mL/h, and a third solution including the core, the first interface fusion layer, the first layer, the second interfacial fusion layer, and the second layer was obtained by a mixing reaction for 20 minutes.

In step S400, a mixture consisting of 1 mL of the Se-TOP solution and 2.5 mL of the cadmium oleate solution was injected into the third solution at 290° C. with a rate of 8 mL/h to form the third layer, then another mixture consisting of 1 mL of the S-TOP solution and 2.5 mL of the cadmium oleate solution was added with a rate of 10 mL/h, and the fourth solution including the core, the first interface fusion layer, the first layer, the second interfacial fusion layer, the second layer, the third layer, and the fourth layer was obtained by a reaction.

In step S500, 2 mL of the Zn(DDTC)₂ solution was injected into the fourth solution at 150° C., and a product including the quantum dot was obtained by a reaction for 10 minutes.

In step S600, 40 mL of n-hexane and 40 mL of ethyl acetate were added into a centrifuge tube, then the product including the quantum dot and 60 mL of ethanol were sequentially added into the centrifuge tube, after shaking evenly, the centrifuge tube was centrifuged at 10000 r/min for 5 minutes, and a first precipitate was obtained after removing a supernatant. Subsequently; the first precipitate was re-dissolved with 30 mL of n-hexane, then 15 mL of ethanol was added, after shaking evenly, the centrifuge tube was centrifuged at 10000 r/min for 5 minutes, finally, a second precipitate which was a purified quantum dot was obtained after removing a supernatant.

### Comparative Example 1

The present comparative embodiment provides a quantum dot and a preparation method thereof. Compared with the quantum dot in Example 1, the quantum dot in the present comparative embodiment is different in that the material of the core is Cd_{0.2}Zn_{0.8}Se, the average particle size of the core is 6 nm, and the first interface fusion layer, the first layer, the second interfacial fusion layer, and the second layer are omitted.

Compared with the method for preparing the quantum dot in Example 1, a method for preparing the quantum dot in the present comparative embodiment is different in that step S20 and step S30 are omitted, and step S10 is replaced with “10 mL of the zinc oleate solution was added into a three-necked flask, after heating the zinc oleate solution to 310° C., a mixture consisting of 0.5 mL of the Se-TOP solution and 1 mL of the cadmium oleate solution was injected into the zinc oleate solution, and a third solution including the core was obtained by ripening for 20 minutes”.

### Comparative Example 2

The present comparative embodiment provides a quantum dot. The quantum dot is Cd_{0.1}Zn_{0.9}Se/Cd_{0.3}Zn_{0.7}S/ZnS, where an average particle size of a core is 4 nm, an average thickness of an intermediate shell is 2 nm, and an average thickness of the outermost shell is 1 nm.

Test Example 1

Energy levels of quantum dots in Examples 1 to 6, Comparative Example 1 and Comparative Example 2 were detected by an ultraviolet electron spectrometer. Energy levels of the integral structure of quantum dots of Example 1, Example 2, and Example 6 are shown in Table 1 below:

TABLE 1

| | the integral structure | ΔE_{V1} | ΔE_{C1} | ΔE_{V2} | ΔE_{C2} |
|---|---|---|---|---|---|
| items | (core/first layer/second layer) | (eV) | (eV) | (eV) | (eV) |
| Example 1 | ZnS/CdSe/Cd_{0.2}Zn_{0.8}Se | −0.4 | 0.35 | 0.3 | −0.25 |
| Example 2 | ZnS/CdSe/Cd_{0.5}Zn_{0.5}Se | −0.35 | 0.32 | 0.25 | −0.23 |
| Example 6 | ZnSe/CdSe/Cd_{0.5}Zn_{0.5}S | −0.33 | 0.3 | 0.28 | −0.22 |

In Table 1, ΔE_{V1} refers to a difference between a valance band maximum of the core and the valance band maximum of the first layer, ΔE_{C1} refers to a difference between a conduction band minimum of the core and the conduction band minimum of the first layer, ΔE_{V2} refers to a difference between the valance band maximum of the first layer and the valance band maximum of the second layer, and ΔE_{C2} refers to a difference between the conduction band minimum of the first layer and the valance band maximum of the second layer.

Furthermore, for the quantum dot in Example 1, a band gap of the integral structure is 3.6 eV, a band gap of the first layer is 1.9 eV, and a band gap of the second layer is 2.4 eV. For the quantum dot in Example 1, a band gap of the integral structure is 2.7 eV, a band gap of the first layer is 2.4 eV, and a band gap of the second layer is 2.6 eV.

Energy levels of partial layers of quantum dots in Examples 1 to 6, Comparative Example 1, and Comparative Example 2 are shown in Table 2 below:

TABLE 2

| | third | ΔE_{V3} | ΔE_{C3} | fourth | ΔE_{V4} | ΔE_{C4} | fifth | ΔE_{V5} | ΔE_{C5} |
|---|---|---|---|---|---|---|---|---|---|
| items | layer | (eV) | (eV) | layer | (eV) | (eV) | layer | (eV) | (eV) |
| Example 1 | ZnSe | −0.1 | 0.3 | CdS | −0.3 | 0.1 | ZnS | −0.4 | 0.35 |
| Example 2 | ZnSe | −0.12 | 0.28 | CdS | −0.27 | 0.15 | ZnS | −0.42 | 0.38 |
| Example 3 | ZnSe | −0.1 | 0.3 | none | none | none | ZnS | −0.4 | 0.35 |
| Example 4 | none | none | none | CdS | −0.3 | 0.1 | ZnS | −0.4 | 0.35 |
| Example 5 | ZnSe | −0.1 | 0.3 | CdS | −0.3 | 0.1 | ZnS | −0.4 | 0.35 |
| Example 6 | Cd_{0.2}Zn_{0.8}Se | −0.08 | 0.25 | Cd_{0.6}Zn_{0.4}S | −0.26 | 0.08 | ZnS | −0.38 | 0.42 |
| Comparative | ZnSe | −0.15 | 0.25 | CdS | −0.28 | 0.12 | ZnS | −0.44 | 0.3 |
| Example 1 | | | | | | | | | |
| Comparative | none | none | none | Cd_{0.3}Zn_{0.7}S | −0.2 | 0.1 | ZnS | −0.35 | 0.37 |
| Example 2 | | | | | | | | | |

In Table 2, ΔE_{V3} refers to a difference between the valance band maximum of the third layer and the valance band maximum of the integral structure, and ΔE_{C3} refers to a difference between the conduction band minimum of the integral structure and the conduction band minimum of the third layer. ΔE_{V4} refers to a difference between the valance band maximum of the fourth layer and the valance band maximum of the integral structure, and ΔE_{C4} refers to a difference between the conduction band minimum of the integral structure and the conduction band minimum of the fourth layer. ΔE_{V5} refers to a difference between the valance band maximum of the fifth layer and the valance band maximum of the integral structure, and ΔE_{C5} refers to a difference between the conduction band minimum of the integral structure and the conduction band minimum of the fifth layer.

A Photoluminescence wavelength, a full width at half maximum, and a photoluminescence efficiency of the quantum dot in each of Examples 1 to 6, Comparative Example 1, and Comparative Example 2 are shown in Table 3 below:

TABLE 3

| | photoluminescence | full width at | photoluminescence |
|---|---|---|---|
| | wavelength | half maximum | efficiency |
| items | (nm) | (nm) | (%) |
| Example 1 | 470 | 18 | 85 |
| Example 2 | 473 | 17 | 87 |
| Example 3 | 469 | 16 | 86 |
| Example 4 | 468 | 17 | 84 |
| Example 5 | 468 | 19 | 85 |
| Example 6 | 472 | 19 | 87 |
| Comparative | 470 | 20 | 75 |
| Example 1 | | | |
| Comparative | 471 | 18 | 67 |
| Example 2 | | | |

### Device Example 1

The present embodiment provides a photoelectric device and a preparation method thereof. The photoelectric device is a quantum dot light emitting diode with an upright structure. Referring to FIG. 4, the photoelectric device 10 includes an anode 101, a hole functional layer 105, a light-emitting layer 103, an electron functional layer 104, and cathode 102 disposed sequentially in stack. The hole functional layer 105 is formed of a hole injection layer 1051 and a hole transport layer 1052 disposed in stack, and the hole injection layer 1051 is closer to the anode 101 than the hole transport layer 1052. The electron functional layer 104 has a single-layer structure, and the electron functional layer 104 is an electron transport layer.

A material of the anode 101 is ITO, and an average thickness of the anode 101 is 80 nm. A material of the cathode 102 is silver, and an average thickness of the cathode 102 is 100 nm. A material of the hole injection layer 1051 is PEDOT:PSS, and an average thickness of the hole injection layer 1051 is 40 nm. A material of the hole transport layer 1052 is TFB, and an average thickness of the hole transport layer 1052 is 30 nm. A material of the light-emitting layer 103 is the quantum dot in Example 1, and an average thickness of the light-emitting layer 103 is 40 nm. A material of the electron functional layer 104 is Zn_{0.85}Mg_{0.15}O nanoparticles, an average particle size of Zn_{0.85}Mg_{0.15}O nanoparticles is 5 nm, and an average thickness of the electron functional layer 104 is 40 nm.

A method for preparing the photoelectric device includes steps S10.1˜S10.6.

In step S10.1, ITO was sputtered on one side of a substrate made of glass to obtain an ITO layer. A surface of the ITO layer was wiped with a cotton swab dipped in a small amount of soapy water to remove visible impurities on the surface. The substrate including the ITO layer was ultrasonically cleaned by deionized water for 15 minutes, acetone for 15 minutes, ethanol for 15 minutes and isopropyl alcohol for 15 minutes sequentially, and after drying, the substrate including the anode was obtained by an ultraviolet-ozone surface treatment for 15 minutes.

In step S10.2, under an air atmosphere with a normal temperature and a normal pressure, a PEDOT:PSS aqueous solution was spin-coated on one side of the anode away from the substrate, and then the hole injection layer was formed by heating at 150° C. under a nitrogen atmosphere for curing.

In step S10.3, under a nitrogen atmosphere with a normal temperature and a normal pressure, a TFB solution with a concentration of 8 mg/mL was spin-coated on one side of the hole injection layer away from the anode, and then the hole transport layer was formed by heating at 150° C. under a nitrogen atmosphere for curing. A solvent of the TFB solution is chlorobenzene.

In step S10.4, under a nitrogen atmosphere with a normal temperature and a normal pressure, a quantum dot solution with a concentration of 25 mg/mL was spin-coated on one side of the hole transport layer away from the hole injection layer, and then the light-emitting layer was formed by heating at 80° C. under a nitrogen atmosphere for curing. A solvent of the quantum dot solution was n-hexane.

In step S10.5, under a nitrogen atmosphere with a normal temperature and a normal pressure, a Zn_{0.85}Mg_{0.15}O nanoparticles solution with a concentration of 30 mg/mL was spin-coated on one side of the light-emitting layer away from the hole transport layer, and then the electron functional layer was formed by heating at 100° C. under a nitrogen atmosphere for curing. A solvent of the Zn_{0.85}Mg_{0.15}O nanoparticles solution is ethanol.

In step S10.6, a laminated structure obtained after the step S10.5 was placed in a vacuum coating machine with a vacuum degree of 4×10⁶ mbar, then the cathode was formed on one side of the electron functional layer away from the light-emitting layer by evaporating silver through a mask plate, and finally an UV-curable adhesive was used for encapsulation to obtain the photoelectric device.

### Device Example 2

The present embodiment provides a photoelectric device and a preparation method thereof. Compared with the photoelectric device in Device Example 1, the photoelectric device in the present embodiment is different in that the material of the light-emitting layer is the quantum dot in Example 2.

A method for preparing the photoelectric device of the present embodiment was carried out with reference to Device Example 1.

### Device Example 3

The present embodiment provides a photoelectric device and a preparation method thereof. Compared with the photoelectric device in Device Example 1, the photoelectric device in the present embodiment is different in that the material of the light-emitting layer is the quantum dot in Example 3.

A method for preparing the photoelectric device of the present embodiment was carried out with reference to Device Example 1.

### Device Example 4

The present embodiment provides a photoelectric device and a preparation method thereof. Compared with the photoelectric device in Device Example 1, the photoelectric device in the present embodiment is different in that the material of the light-emitting layer is the quantum dot in Example 4.

A method for preparing the photoelectric device of the present embodiment was carried out with reference to Device Example 1.

### Device Example 5

The present embodiment provides a photoelectric device and a preparation method thereof. Compared with the photoelectric device in Device Example 1, the photoelectric device in the present embodiment is different in that the material of the light-emitting layer is the quantum dot in Example 5.

A method for preparing the photoelectric device of the present embodiment was carried out with reference to Device Example 1.

### Device Example 6

The present embodiment provides a photoelectric device and a preparation method thereof. Compared with the photoelectric device in Device Example 1, the photoelectric device in the present embodiment is different in that the material of the light-emitting layer is the quantum dot in Example 6.

A method for preparing the photoelectric device of the present embodiment was carried out with reference to Device Example 1.

### Device Comparative Example 1

The present comparative embodiment provides a photoelectric device and a preparation method thereof. Compared with the photoelectric device in Device Example 1, the photoelectric device in the present comparative embodiment is different in that the material of the light-emitting layer is the quantum dot in Comparative Example 1.

A method for preparing the photoelectric device of the present comparative embodiment was carried out with reference to Device Example 1.

### Device Comparative Example 2

The present comparative embodiment provides a photoelectric device and a preparation method thereof. Compared with the photoelectric device in Device Example 1, the photoelectric device in the present comparative embodiment is different in that the material of the light-emitting layer is the quantum dot in Comparative Example 2.

A method for preparing the photoelectric device of the present comparative embodiment was carried out with reference to Device Example 1.

### Test Example 2

Performances of photoelectric devices in Device Examples 1 to 6, Device Comparative Example 1, and Device Comparative Example 2 were tested. A turn-on voltage, currents, a maximum brightness, a luminescence spectrum and other parameters of each photoelectric device were detected by a Fostar FPD optical characteristic measuring equipment, and a lifetime of each photoelectric device was tested by a life testing equipment. Tests were performed in an environment with a temperature of 25° C. and a humidity of 40%.

External quantum efficiency (EQE) was tested by an EQE optical testing instrument, and a maximum external quantum efficiency (EQEₘₐₓ, %) was calculated.

Driven by a constant current (2 mA), the life testing equipment was configured to analyse the lifetime of each photoelectric device. A time required for each photoelectric device to decay from the maximum brightness to 95% thereof was recorded. A time required for each photoelectric device to decay from 100% to 95% at 1000 nit brightness was calculated by attenuation fitting formula, and the time was defined as T95@1000 nit. Test results of photoelectric devices are shown in Table 4 below:

TABLE 4

| | EQEₘₐₓ | T95 |
|---|---|---|
| items | (%) | (h) |
| Device Example 1 | 20 | 180 |
| Device Example 2 | 19 | 150 |
| Device Example 3 | 15.5 | 120 |
| Device Example 4 | 16 | 110 |
| Device Example 5 | 17 | 100 |
| Device Example 6 | 19.5 | 165 |
| Device Comparative | 12 | 70 |
| Example 1 | | |
| Device Comparative | 9 | 50 |
| Example 2 | | |

As can be seen from Table 4, Compared with photoelectric devices in Device Comparative Example 1 and Device Comparative Example 2, a photoelectric performance and the lifetime of each of photoelectric devices in Device Examples 1 to 6 are more advantageous. Taking photoelectric devices in Device Example 1 and Device Comparative Example 2 as examples, the EQEₘₐₓ of the photoelectric device in Device Example 1 is 2.2 times that of the photoelectric device in Device Comparative Example 2, and the T95 of the photoelectric device in Device Example 1 is 3.6 times that of the photoelectric device in Device Comparative Example 2.

Therefore, using the quantum dot of the present disclosure as a light-emitting material of the photoelectric device may beneficial to improving a performance stability of the photoelectric device. On the one hand, an overall structure of the quantum dot is a large-size well structure, which is beneficial to increasing an exciton confinement effect, binding excitons away from the surface of the quantum dot, preventing excitons from being trapped by surface defects, and improving the fluorescence quantum efficiency of the quantum dot. On the other hand, a probability of non-radiative Auger recombination is reduced by designing a layer structure to obtain a long exciton lifetime.

A quantum dot and a preparation method thereof, and a photoelectric device of the present disclosure are described in detail above, and specific examples have been applied herein to illustrate principles and implement measures. The foregoing description of embodiments is provided merely to help understand a method and a core idea of the present disclosure. Those skilled in the art may change specific embodiments and scope of the present disclosure according to ideas of the present disclosure. In summary, contents of the specification should not be construed as limiting the present disclosure.

What is claimed is:

1. A quantum dot with a core-shell structure, wherein in a radial direction, the quantum dot comprises a core, a first layer wrapping the core, and a second layer wrapping the first layer disposed sequentially: a band gap of the first layer is less than a band gap of the core, and the band gap of the first layer is less than a band gap of the second layer.

2. The quantum dot according to claim 1, wherein the band gap of the second layer is less than or equal to the band gap of the core.

3. The quantum dot according to claim 1, wherein a difference between a valance band maximum of the core and a valance band maximum of the first layer is less than or equal to −0.2 eV. a difference between a conduction band minimum of the core and a conduction band minimum of the first layer is greater than or equal to 0.2 eV. a difference between the valance band maximum of the first layer and a valance band maximum of the second layer is greater than or equal to 0.2 eV, and a difference between the conduction band minimum of the first layer and a conduction band minimum of the second layer is less than or equal to −0.2 eV.

4. The quantum dot according to claim 1, wherein the quantum dot is a blue quantum dot, and an emission wavelength of the quantum dot is not greater than 475 nm.

5. The quantum dot according to claim 1, wherein an average particle size of the core ranges from 2 nm to 8 nm, an average thickness of the first layer ranges from 1 nm to 3 nm, an average thickness of the second layer ranges from 1 nm to 4 nm, and an average particle size of the quantum dot ranges from 4 nm to 15 nm.

6. The quantum dot according to claim 1, wherein a material of the core is a first compound, a material of the first layer is a second compound, and a material of the second layer is a third compound:
the quantum dot further comprises a first interfacial fusion layer between the core and the first layer, where a material of the first interfacial fusion layer comprises the first compound and the second compound, and along a radial direction from the core to the first layer, a mole percentage of the first compound gradually decreases and a mole percentage of the second compound gradually increases: and
the quantum dot further comprises a second interfacial fusion layer between the first layer and the second layer, where a material of the second interfacial fusion layer comprises the second compound and the third compound, and along a radial direction from the first layer to the second layer, a mole percentage of the second compound gradually decreases and a mole percentage of the third compound gradually increases.

7. The quantum dot according to claim 1, wherein a material of the core, a material of the first layer, and a material of the second layer are each independently selected from one or more of a group II-VI compound, a group IV-VI compound, a group III-V compound, a group III-VI compound, and a group I-III-VI compound;
the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound includes but not limited to one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-VI compound is selected from one or more of In₂S₃, In₂Se₃, InGaS₃, and InGaSe₃, the group III-V compound is selected from one or more of GaN, GaP. GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and the group I-III-VI compound is selected from one or more of AgInS, AgInS₂, CuInS. CuInS₂, AgGaS₂, CuGaS₂, CuGaO₂, AgGaO₂, AgAlO₂, AgInGaS₂, and CuInGaS₂.

8. The quantum dot according to claim 7, wherein the material of the core is ZnA, the material of the first layer is CdM, and the material of the second layer is CdₓZn₍₁₋ₓ₎Z, where A, M, and Z are each independently selected from Se or S, and x is greater than or equal to 0.2 and less than or equal to 0.5.

9. The quantum dot according to claim 1, wherein the quantum dot further comprises at least one layer wrapping the core, the first layer, and the second layer, where the at least one layer is selected from one or more of a third layer with a hole confinement structure, a fourth layer with electron confinement structure, and a fifth layer with a Type I confinement structure;
in the radial direction, the core to the second layer are configured as an integral structure, where an absolute value of a difference between a valance band maximum of the third layer and a valance band maximum of the integral structure is greater than 0 eV and less than or equal to 0.2 eV, and an absolute value of a difference between a conduction band minimum of the integral structure and a conduction band minimum of the third layer is greater than or equal to 0.2 eV and less than or equal to 0.8 eV:
an absolute value of a difference between a valance band maximum of the fourth layer and a valance band maximum of the integral structure is greater than or equal to 0.2 eV and less than or equal to 0.8 eV, and an absolute value of a difference between a conduction band minimum of the integral structure and a conduction band minimum of the fourth layer is greater than 0 eV and less than or equal to 0.2 eV: and an absolute value of a difference between a valance band maximum of the fifth layer and a valance band maximum of the integral structure is greater than or equal to 0.2 eV and less than or equal to 0.8 eV, and an absolute value of a difference between a conduction band minimum of the integral structure and a conduction band minimum of the fifth layer is greater than or equal to 0.2 eV and less than or equal to 0.8 eV.

10. The quantum dot according to claim 9, wherein the quantum dot comprises the third layer and the fifth layer, where the fifth layer is an outermost layer of the quantum dot.

11. The quantum dot according to claim 9, wherein the quantum dot comprises the fourth layer and the fifth layer, where the fifth layer is an outermost layer of the quantum dot.

12. The quantum dot according to claim 9, wherein the quantum dot comprises the third layer, the fourth layer, and the fifth layer, where the fifth layer is an outermost layer of the quantum dot, the fourth layer is disposed between the third layer and the fifth layer or the third layer is disposed between the fourth layer and the fifth layer.

13. The quantum dot according to claim 9, wherein a material of the third layer is Cd_{y1}Zn_{(1-y1)}Se, where y1 is greater than or equal to 0 and less than 1; and
a material of the fourth layer is Cd_{y2}Zn_{(1-y2)}S, where y2 is greater than 0 and less than or equal to 1; and
a material of the fifth layer is ZnS.

14. The quantum dot according to claim 1, a general structure of the quantum dot is ZnA/CdM/CdₓZn₍₁₋ₓ₎ZZ/Cd_{y1}Zn_{(1-y1)}Se/ZnS, or ZnA/CdM/CdₓZn₍₁₋ₓ₎Z/Cd_{y2}Zn_{(1-y2)}S/ZnS, where A, M, and Z are each independently selected from Se or S, x is greater than or equal to 0.2 and less than or equal to 0.5, yl is greater than or equal to 0 and less than 1, and y2 is greater than 0 and less than or equal to 1.

15. A method for preparing a quantum dot comprising:
S1. providing a cationic precursor which is a solution comprising a zinc source and a cadmium source, introducing an inert gas at room temperature to expel air, and heating the cationic precursor to a temperature ranged between 125° C. and 180° C. for 30 minutes˜90 minutes to obtain a basic solution, after the air is completely expelled:
S2. heating the basic solution to a reaction temperature, injecting an anionic precursor into the basic solution, and ripening to obtain a core:
S3. forming multiple shell layers sequentially on a surface of the core to obtain a reaction liquid comprising the quantum dot:
wherein the quantum dot with a core-shell structure, and in a radial direction, the quantum dot comprises a core, a first layer wrapping the core, and a second layer wrapping the first layer disposed sequentially: a band gap of the first layer is less than a band gap of the core, and the band gap of the first layer is less than a band gap of the second layer.

16. The method according to claim 15, wherein a concentration of zinc in the cationic precursor ranges from 0.05 mol/L to 1 mol/L, and the inert gas comprises one or more of nitrogen, argon, helium, neon, krypton, and xenon.

17. A photoelectric device comprising:
an anode;
a cathode; and
multiple functional layers disposed between the anode and the cathode, wherein a material of at least one of the multiple functional layers comprises a quantum dot with a core-shell structure: in a radial direction, the quantum dot comprises a core, a first layer wrapping the core, and a second layer wrapping the first layer disposed sequentially, where a band gap of the first layer is less than a band gap of the core, and the band gap of the first layer is less than a band gap of the second layer.

18. The photoelectric device according to claim 17, wherein the functional layers comprise a light emitting layer comprising the quantum dot.

19. The photoelectric device according to claim 18, wherein the functional layers further comprise an electron functional layer disposed between the light emitting layer and the cathode;
a material of the electron functional layer is selected from one or more of an undoped-type second metal oxide, a group IIB-VIA semiconductor material, and a doped-type third metal oxide, where the undoped-type second metal oxide is selected from one or more of ZnO, TiO₂, and SnO₂, the group IIB-VIA semiconductor material is selected from one or more of ZnS, ZnSe, and CdS, a host material of the doped-type third metal oxide is selected from ZnO, TiO₂, or SnO₂, and a doping element of the doped-type third metal oxide is selected from one or more of Mg, Ca, Zr, W, Ga, Li, Al, Ti, Y, In, and Sn.

20. The photoelectric device according to claim 18, wherein the functional layers further comprise a hole functional layer disposed between the light emitting layer and the anode, where a material of the hole functional layer comprises one or more of an organic compound, a first inorganic compound, and a second inorganic compound;
the organic compound comprises one or more of poly(3,4-ethylenedioxythiophene)-poly(styrenesulfonate), copper (II) phthalocyanine, titanyl phthalocyanine,2,3,5,6-tetrafluoro-7,7,8,8-tetracyanoquinodimethane, hexaazatriphenylenehexacabonitrile, polyaniline, polypyrrole, poly(3-hexylthiophene-2,5-diyl), poly(n-vinylcarbazole), 4,4′-Bis(N-carbazolyl)-1,1′-biphenyl, poly[N,N′-bis(4-butylphenyl)-N,N′-bis(phenyl)-benzi, 4,4′-cyclohexylidenebis[N,N-bis(4-methylphenyl)aniline], poly(9,9-dioctylfluorene-co-N-(4-butylphenyl) diphenylamine), poly[(9,9-dioctylfluorenyl-2,7-diyl)-alt-(4,4′-(N-(4-butylphenyl), 4,4′,4″-tris(N-3-methylphenyl-N-phenylamino) triphenylamine, 4,4′,4″-tris(carbazol-9-yl)-triphenylamine, 4,4′,4″-tris[2-naphthyl (phenyl)amino]triphenylamine, N,N′-bis-(1-naphthalenyl)-N,N′-bis-phenyl-(1,l′-biphenyl)-4,4′-diamine, N,N′-bis(3-methylphenyl)-N,N′-diphenyl-benzidine, N,N′-bis[4-(diphenylamino) phenyl]-N,N′-diphenylbenzidine, N2,N7-diphenyl-N2,N7-di-m-tolyl-9,9′-spirobi[fluorene]-2,7-diamine, N2,N7-di-1-naphthalenyl-poly[bis(4-phenyl)(2,4,6-N2,N7-diphenyl-9,9′-spirobi[9h-fluorene]-2,7-diamine, trimethylphenyl) amine], and 2,2′,7,7′-Tetrakis[N,N-di(4-methoxyphenyl) amino]-9,9′-spirobifluorene; and
the first inorganic compound comprises one or more of graphene, C60, nickel oxide, molybdenum oxide, tungsten oxide, vanadium oxide, p-type gallium nitride, chromium oxide, copper oxide, copper sulfide, molybdenum sulfide, and tungsten sulphide; and
the second inorganic compound comprises at least one doped-type second inorganic compound, where a host compound of the doped-type second inorganic compound is selected from one or more of graphene, C60, nickel oxide, molybdenum oxide, tungsten oxide, vanadium oxide, p-type gallium nitride, chromium oxide, copper oxide, copper sulfide, molybdenum sulfide, or tungsten sulphide, a doping element of the doped-type second inorganic compound is selected from one or more of nickel, molybdenum, tungsten, vanadium, chromium, copper and platinum group metal elements, and a ratio of a molar amount of the doping element to a total molar amount of the doped-type second inorganic compound does not exceed 50%.
